(19) United States
(12) Patent Application Publication
(10) Pub. No.: US 2003/0214020 A1
(43) Pub. Date: Nov. 20, 2003

(54) Embedded package for power semiconductor device

(76) Inventor: Charng Geng Sheen, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/147,816

(22) Filed: May 20, 2002

(51) Int. Cl. H01L 23/02

(52) U.S. Cl. 257/678

(57) ABSTRACT

An embedded package for power semiconductor device comprises a lead, a cup, a semiconductor device, an insulation glue and an isolation glue. The cup has a cavity, an inner wall, a gap and a heat-conductive stage therein. An annulus baffle is formed on the heat-conductive stage. The rigidity between the heat-conduction stage and bottom of the cup is larger than the rigidity between the gap and bottom of the cup to protect the semiconductor device. The semiconductor device is connected between the lead and the heat-conductive stage, and is coated by the insulation glue to prevent from leak. The isolation glue is coated on an outer face of the insulation glue to block moisture.

### FIELD OF THE INVENTION

The present invention relates to an embedded package for power semiconductor device, especially to an embedded package for power semiconductor device, wherein the semiconductor device is coated with insulation glue and isolation glue to prevent from damage at high-temperature operation.

### BACKGROUND OF THE INVENTION

As shown in FIGS. 1 and 2, the conventional embedded package for power semiconductor device comprises a lead 10a, a cup 20a and a semiconductor device 30a connected to the lead 10a and the cup 20a. The cup 20a contains an inner wall 21a therein and a cavity 21a. A compound resin 40a is filled within the cavity 21a to protect the semiconductor device 30a therein. Afterward, the semiconductor package is embedded in a hole 51a of a board 50a for connecting to other devices.

However, in above-mentioned semiconductor package, the semiconductor device 30a has difficulty to place exactly at center of the cavity 21a due to the structure of the cup 20a. The filled compound resin 40a is used to protect the semiconductor device 30a. However, the critical temperature of the compound resin 40a is only 175° C. and the compound resin 40a is tended to have cleavage due to thermal shock, resin hardening or mechanical impact. Moisture may invade through the cleavage to degrade the semiconductor device 30a. Moreover, the compound resin 40a has not sufficient electric isolation and the lifetime of the semiconductor device 30a is degraded due to leak.

Moreover, the semiconductor package is embedded in the hole 51a of the board 50a and the cup 20a is liable to deform. The semiconductor device 30a in the cavity 21a has cleavage problem when the bottom of the cup 20a is deformed, especially at the edge of the semiconductor device 30a.

### SUMMARY OF THE INVENTION

It is the object of the present invention to provide an embedded package for power semiconductor device, wherein the semiconductor device is prevented from damage at high-temperature operation.

In one aspect of the present invention, the cup has gap and heat-conducting stage therein such that the thickness between the heat-conduction stage and bottom of the cup is larger than the thickness between the gap and bottom of the cup. Therefore, the rigidity between the heat-conduction stage and bottom of the cup is larger than the rigidity between the gap and bottom of the cup. When the embedded package for power semiconductor device is embedded to a hole on a board, the stress force is concentrated at the gap and the warp of the heat-conduction stage is reduced.

In another aspect of the present invention, an annulus baffle is provided on the heat-conduction stage to align the semiconductor device at the center of the heat-conducting stage.

In still another aspect of the present invention, a heat-resistant insulation glue is coated on the semiconductor device to insulate the semiconductor device from non-contact region.

In still another aspect of the present invention, an isolation glue is coated on an outer face of the insulation glue to block moisture for the semiconductor device.

To achieve above object, the present invention provides an embedded package for power semiconductor device comprising a lead, a cup, a semiconductor device, an insulation glue and an isolation glue. The cup has a cavity, an inner wall, a gap and a heat-conductive stage therein. The cavity, the gap and the heat-conductive stage are symmetrically provided in the cup. An annulus baffle is formed on the heat-conductive stage. The rigidity between the heat-conduction stage and bottom of the cup is larger than the rigidity between the gap and bottom of the cup to protect the semiconductor device. The semiconductor device is connected between the lead and the heat-conductive stage, and is coated by the insulation glue to prevent from leak. The isolation glue is coated on an outer face of the insulation glue to block moisture.

The various objects and advantages of the present invention will be more readily understood from the following detailed description when read in conjunction with the appended drawing, in which:

### BRIEF DESCRIPTION OF THE DRAWING

FIG. 1 shows a sectional view of a prior art embedded package for power semiconductor device;

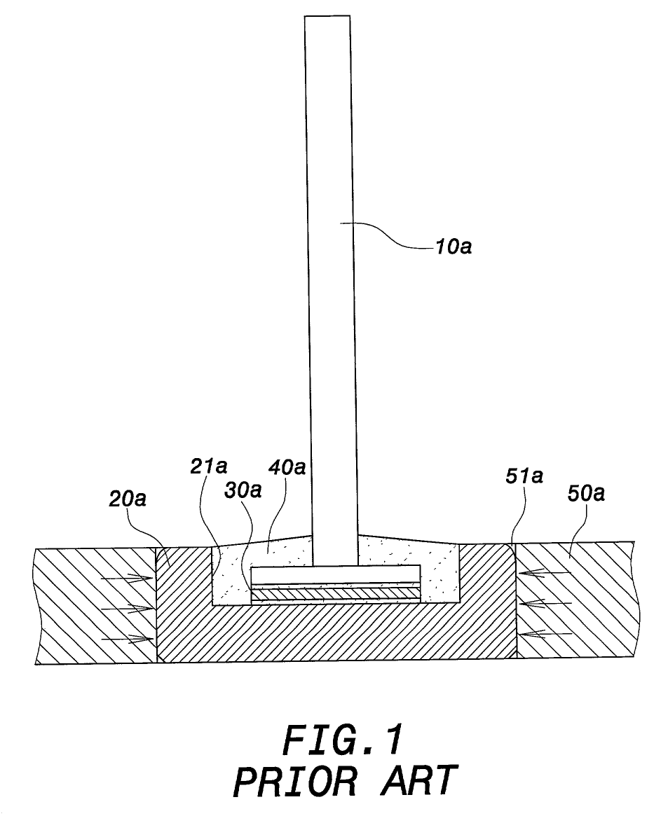

FIG. 2 shows a sectional view of a cup in a prior art embedded package for power semiconductor device;

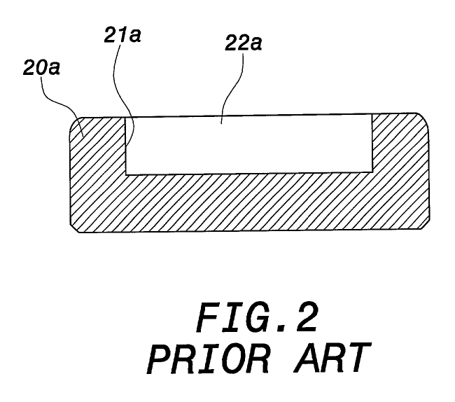

FIG. 3 shows a sectional view of the embedded package for power semiconductor device according to the present invention;

FIG. 3A shows a partially sectional view of the embedded package for power semiconductor device; and

FIG. 4 shows a sectional view of the cup in the embedded package for power semiconductor device.

### DETAILED DESCRIPTION OF THE INVENTION

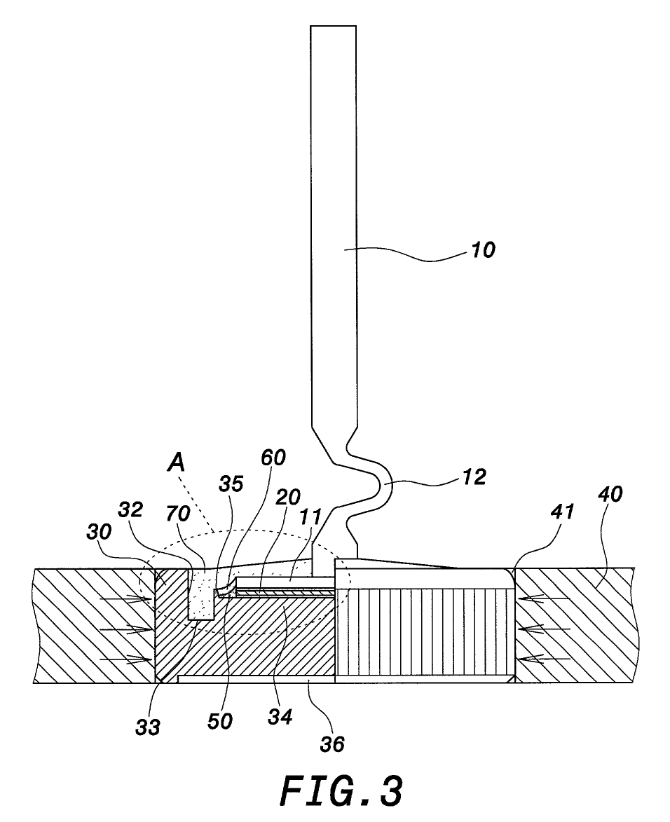

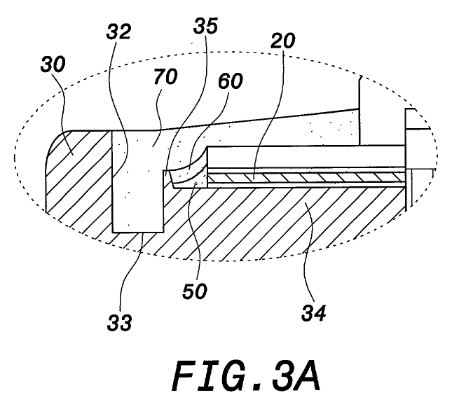

The present invention is intended to provide an embedded package for power semiconductor device. As shown in FIG. 3, the embedded package of the present invention comprises a lead 10, a semiconductor device 20, and a cup 30. The semiconductor device 20 is connected to the lead 10 and the cup 30 and then the embedded package is embedded into a hole 41 on a board 40 for connecting to other devices.

FIG. 3 shows the sectional view of the embedded package for power semiconductor device according to the present invention. The lead 10 comprises a base 11 and a bent portion 12 to provide electric and mechanic connection to other devices.

The semiconductor device 20 is a power semiconductor device connected to the lead 10.

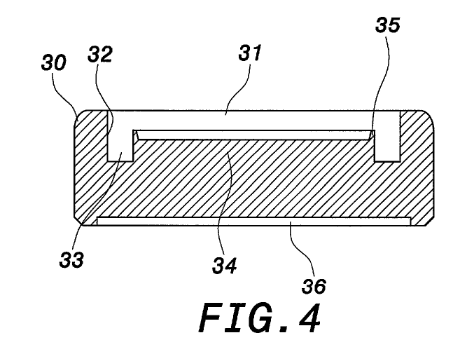

FIG. 3A shows a partially sectional view of the embedded package for power semiconductor device and FIG. 4 shows the sectional view of the cup 30 in the embedded package for power semiconductor device. The cup 30 has a cavity 31, an inner wall 32, a gap 33 and a heat-conduction stage 34. The thickness between the heat-conduction stage 34 and bottom of the cup 30 is larger than the thickness between the gap 33 and bottom of the cup 30. Therefore, the rigidity between the heat-conduction stage 34 and bottom of the cup 30 is larger than the rigidity between the gap 33 and bottom of the cup 30. The heat-conduction stage 34 has an annulus baffle 35 to facilitate the semiconductor device 20 to place at the center of the heat-conduction stage 34, i.e., the center of the cavity 31. The cup 30 has a dent 36 on bottom thereof.

The semiconductor device 20 is coated with insulation glue 50 on lateral face thereof and the lead 10 is coated with insulation glue 50 on lateral face thereof. The annulus baffle 35 of the heat-conduction stage 34 prevents the insulation glue 50 from flowing into the gap 33 of the cup 30. In this way, the semiconductor device 20 is hermetically fixed on the heat-conduction stage 34. The insulation glue 50 can be heat-resistant and highly insulative material such as polyimide. The heat-resistant and highly insulative property of polyimide can ensure the insulation for non-contact region between the semiconductor device 20 and the heat-conduction stage 34, and the insulation for non-contact region between the semiconductor device 20 and the lead 10. Therefore, the leak problem of the semiconductor device 20 can be prevented at high temperature and low temperature operation environment.

The portion of the lead 10 above the insulation glue 50 is coated with isolation glue 60 on a lateral face thereof. The annulus baffle 35 of the heat-conduction stage 34 prevents the isolation glue 60 from flowing into the gap 33 of the cup 30. Therefore, the isolation glue 60 is provided outside the insulation glue 50 and prevents moisture from invading into the insulation glue 50 and the semiconductor device 20, thus protecting the semiconductor device 20. The isolation glue 60 is made of waterproof material such as epoxy, whereby the semiconductor device 20 is isolated from moisture even though at high-temperature operation. Moreover, a buffer body 70 is filled to the cavity 31 to further protect the semiconductor device 20 on the heat-conduction stage 34.

The embedded package for power semiconductor device is embedded to the hole 41 on the board 40, whereby the semiconductor device 20 encapsulated by the embedded package can be used by other device. The lateral face of the cup 30 is subjected to the pressure from the circumference of the hole 41 such that the bottom portion of the cup 30 has warped problem. On virtue that the rigidity between the heat-conduction stage 34 and bottom of the cup 30 is larger than the rigidity between the gap 33 and bottom of the cup 30, the stress force is concentrated at the gap 33 and the warp of the heat-conduction stage 34 is reduced. The semiconductor device 20 is subjected to an impact force when the embedded package for power semiconductor device is embedded to the hole 41 on the board 40. The buffer body 70 filled in the cavity 31 is used to reduce the impact force of the semiconductor device 20. The buffer body 70 can be Si resin material and is tightly attached to the inner wall 32 and the lead 10. Moreover, the Si resin material also provides damp proof and weather ability.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim

1. An embedded package for power semiconductor device, comprising
a lead;
a semiconductor device connected to the lead;
a cup having a cavity, an inner wall, a gap and a heat-conductive stage therein, an annulus baffle formed on the heat-conductive stage and the heat-conductive stage being connected to the semiconductor device;
an insulation glue coated on the semiconductor device and the heat-conductive stage to provide an insulation between the semiconductor device and a portion of the lead not contacting the semiconductor device, and
an insulation between the semiconductor device and a portion of the heat-conductive stage not contacting the semiconductor device; and
an isolation glue coated on an outer face of the insulation glue.

2. The embedded package for power semiconductor device as in claim 1, wherein the insulation glue is polyimide.

3. The embedded package for power semiconductor device as in claim 1, wherein the isolation glue is epoxy.

4. The embedded package for power semiconductor device as in claim 1, further comprising a buffer body made of Si resin and filled into the cavity, the Si resin buffer body being tightly attached to the inner wall, the gap, the heat-conductive stage and the lead, thus protecting the semiconductor device.

5. The embedded package for power semiconductor device as in claim 1, wherein the heat-conductive stage, the cavity and the gap are symmetrically arranged in the cup, the semiconductor device is retained by the annulus baffle and can be facilitated to place at a center of the heat-conductive stage.

6. The embedded package for power semiconductor device as in claim 1, wherein the lead has a bent portion.

7. The embedded package for power semiconductor device as in claim 1, wherein the cup has a dent on bottom thereof.
